(19) United States
(12) Patent Application Publication
(10) Pub. No.: US 2003/0027388 A1
(43) Pub. Date: Feb. 6, 2003

(54) Method for forming tunnel oxide film of flash memory

(75) Inventors: Chin-Ta Su, Erluen (TW); Tzung-Ting Han, Ilan City (TW)

Correspondence Address: LOWE HAUPTMAN GOPSTEIN GILMAN & BERNER, LLP, Suite 310, 1700 Diagonal Road, Alexandria, VA, 22314, US

(73) Assignee: Macronix International Co., Ltd.

(21) Appl. No.: 10/073,039

(22) Filed: Feb. 12, 2002

(30) Foreign Application Priority Data
Aug. 6, 2001 (TW) 90119181

(51) Int. Cl. H01L 21/336

(52) U.S. Cl. 438/257

(57) ABSTRACT

A method for forming a tunnel oxide film of a flash memory. A chamber having a wafer therein is provided. Hydrogen and oxygen are introduced into the chamber, whereby the chamber has a pressure and a temperature therein. The pressure of the chamber is decreased to about 5-15 torrs. The temperature of the chamber is increased to about 850° C. to about 1100° C., whereby the hydrogen reacts with the oxygen to form a plurality of oxygen radicals, and whereby the oxygen radicals react with the wafer to form a silicon oxide film.

### BACKGROUND OF THE INVENTION

(1) Field of the Invention

The invention relates to a semiconductor process, and more particularly to a process for forming a tunnel oxide film of a flash memory.

(2) Description of the Prior Art

Electrically erasable programmable read-only-memories (EEPROMs) are widely used as memory components for personal computers and electronic equipment. A conventional EEPROM memory cell comprises a floating gate transistor structure which is programmable, erasable and able to store data. The EEPROM device allows data or programs to be erased or written in a bit by bit manner. However, the conventional EEPROM suffers from a slow storage and retrieval time of typically around 150 ns to 200 ns. Recently, a faster EEPROM, such as a flash memory, has been developed having a storage and retrieval time of about 70 ns to 80 ns. By using the flash memory, the data or programs are erased or written in a block by block manner. In this way, only one or two seconds are needed to compete an erasing action.

FIG. 1 is a cross-sectional schematic diagram of a conventional flash memory. Referring to FIG. 1, a flash memory comprises a tunnel oxide film 102, a first polysilicon 104, an oxygen-nitrogen-oxygen (ONO) film 106 and a second polysilicon 108. The first polysilicon 104, serving as a floating gate 104, is for saving electric charges. The second polysilicon 108, serving as a control gate 108, is for controlling the flash memory. In operation of the flash memory, electronics tunnel through an extremely thin tunnel oxide film 102 to the floating gate 104 and are limited therein. In this case, the control gate 108 needs a greater amount of voltage for turning on the flash memory.

Referring to FIG. 2, a tunnel oxide film is conventionally formed with a furnace 200. Using the furnace 200 to grow a tunnel oxide film consumes a lot of time. In a wafer, the deterioration decreases the uniformity of the film thickness.

Referring to FIG. 3, there is shown a cross-sectional diagram of a layer grown with a conventional furnace. In the growing process, oxygen 302 is introduced into the furnace. Such oxygen 302 reacts with silicon 300 to form silicon dioxide 304. Another way to form silicon dioxide 304 is to introduce gaseous water (H₂O) 306 and the gaseous water is then diffused to silicon 300 and reacts with the silicon 300 to form silicon dioxide 304. Both methods grow tunnel oxide film having unsatisfactory quality. It should be noted that a tunnel oxide film has electronics tunneling therethrough, and the quality of such a tunnel oxide film is therefore highly required. Accordingly, a furnace technology needs to be improved to meet the quality requirement for the formation of a tunnel oxide film.

In short, using a furnace to grow a film is time-consuming, and the quality of the grown film is often unsatisfactory.

### SUMMARY OF THE INVENTION

A purpose of the present invention is to grow a tunnel oxide film by using oxygen radicals, thereby improving the quality of the formed tunnel oxide film. The suggested method can be applied to a semiconductor process.

To achieve the above or other purpose, the present invention provides a method for forming a tunnel oxide film of a flash memory. A chamber having a wafer therein is provided. Hydrogen and oxygen are introduced into the chamber. The pressure of the chamber is decreased to about 5-15 torrs. The temperature of the chamber is increased to about 850° C.-1100° C., thereby reacting the hydrogen with the oxygen to form a plurality of oxygen radicals, whereby the oxygen radicals react with the wafer to form a silicon oxide film.

According to a preferred embodiment of the present invention, the chamber has a plurality of light bulbs for increasing the temperature of the chamber. Moreover, the method further comprises a step of adjusting the light bulbs to uniform the thickness of the silicon oxide film. Furthermore, the volume of the hydrogen divided by the total volume of the hydrogen and the oxygen is preferably ranged from about 1% to about 33%.

In another aspect, the present invention provides a method for forming a tunnel oxide film. A chamber is provided for reaction of only one wafer. A plurality of oxygen radicals are generated in the chamber. The generated oxygen radicals react with the wafer to form a silicon oxide film in the chamber ο Such a tunnel oxide film, comparing to that of the conventional furnace technology, has an improved and satisfactory quality.

### BRIEF DESCRIPTION OF THE DRAWINGS

FIG. 1 is a cross-sectional schematic diagram of a conventional flash memory;

FIG. 2 is a cross-sectional schematic diagram of a conventional furnace;

FIG. 3 is a cross-sectional diagram of a layer grown with a conventional furnace;

FIG. 4 is a cross-sectional and schematic diagram of a chamber having a plurality of light bulbs;

FIG. 5 is an enlarged and schematic diagram of a wafer 404 of FIG. 4; and

FIG. 6 schematically shows that some oxygen radicals are provided and diffused to silicon to form silicon dioxide 604 in a single-wafer processing.

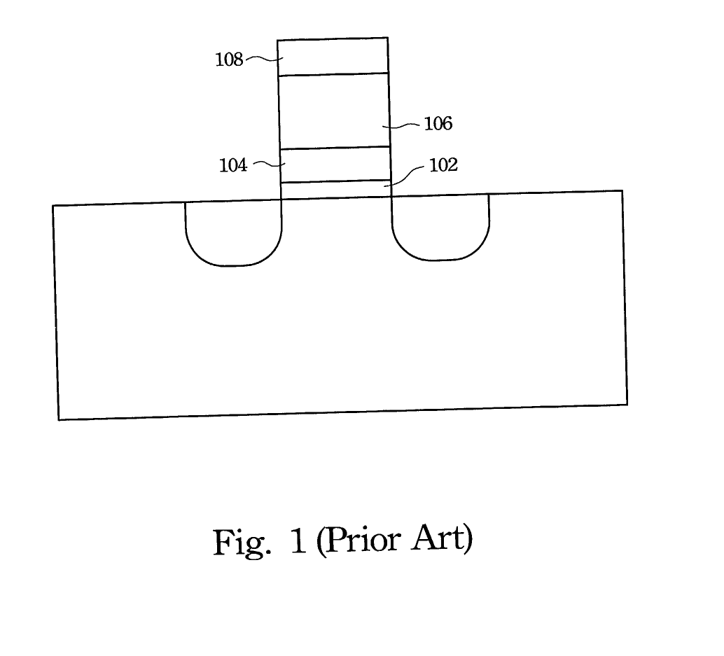

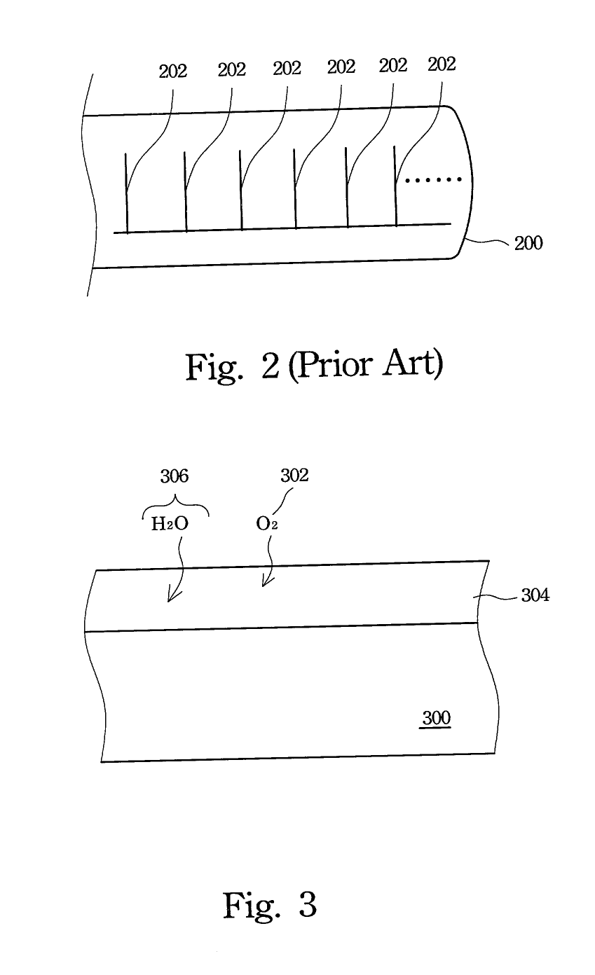

### DESCRIPTION OF THE PREFERRED EMBODIMENTS

The present invention comprises a basic concept of using a new process technology to provide a tunnel oxide film with high quality.

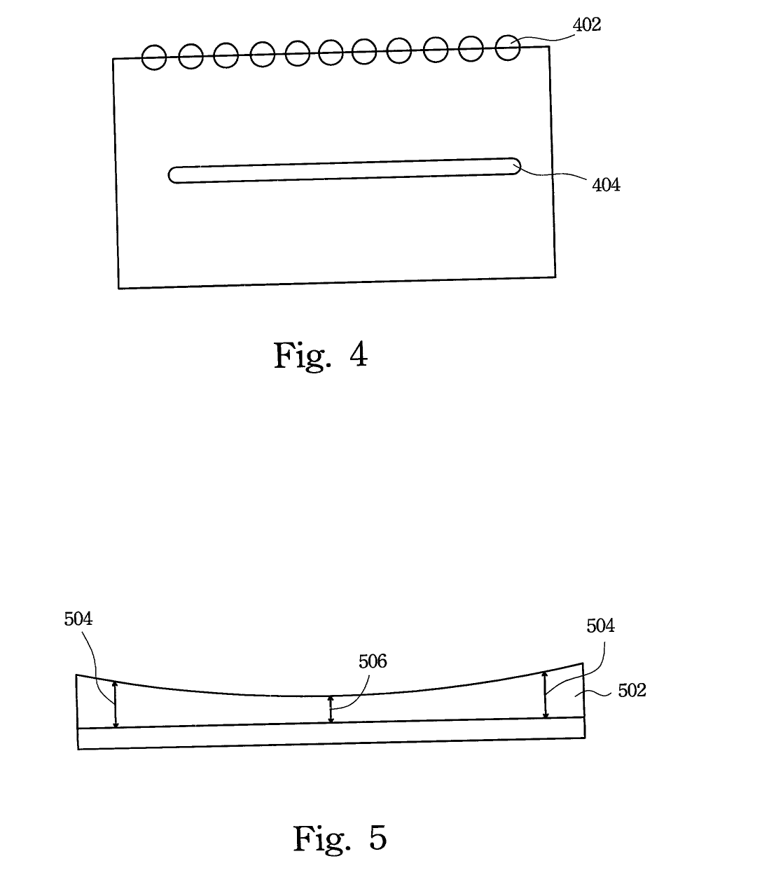

In each process of this present invention, only one wafer is thermally processed (i.e., single-wafer processing). Referring to FIG. 4, a chamber is shown and the chamber has a plurality of light bulbs 402 for increasing the temperature of the chamber therein. The light bulbs 402, honeycombedly disposed over the wafer 404, have a number of about 100-200. Referring to FIG. 5, there is shown a enlarged and schematic diagram of a wafer 404 of FIG. 4. Provided a film 502, grown on and from the wafer 404 in the chamber, if it has a edge thickness greater than the center thickness, the light bulbs 402 will be adjusted to have a center power greater than the edge power. In this way, the power difference could compensate the thickness difference, thereby uniforming the thickness of the grown film. Accordingly, using such a chamber to grown a film on a wafer has a thickness-control capability superior than that of a conventional furnace technology.

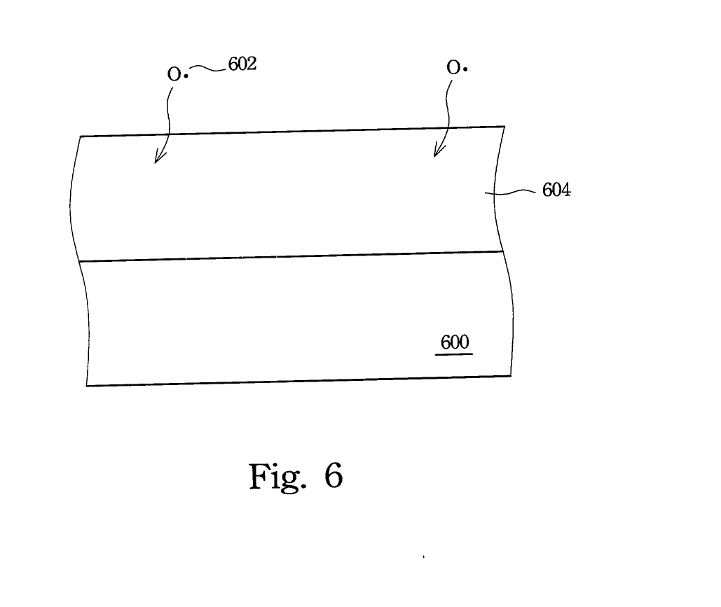

Referring to FIG. 6, oxygen radicals 602 are provided and diffused to silicon 600 to form silicon dioxide 604 in a single-wafer processing. The formed silicon dioxide 604 unavoidably has some defects, but would be soon mended with the high reactivity of oxygen radicals 602. Therefor, the final silicon oxide film has a satisfactory quality. It is noted that because the silicon oxide film serves as a tunnel oxide film having electronics tunneled therethrough, its quality is highly required. This is also a reason single-wafer processing is suggested to grow such a silicon oxide film serving as the desired tunnel oxide film.

The above-described oxygen radicals can be formed by, for example, but not limited to plasma processing or rapid thermal processing (RTP).

Being compared to the present invention, a conventional furnace technology does little to the compensation of film thickness. The temperature adjustment of a furnace is merely for a group of wafers, not for a single wafer. In the present invention, however, the temperature of a chamber is adjusted for only one wafer.

The chamber of the present invention can be conditioned as follows:

(1) The volume of the hydrogen divided by the total volume of the hydrogen and the oxygen: about 1% to about 33%.

(2) Pressure: 5˜15 torrs

(3) Temperature: 850° C.˜1100° C.

More specifically, the hydrogen and the oxygen are introduced into the chamber. The pressure of the chamber is decreased to about 5-15 torrs. The temperature of the chamber is increased to about 850° C. to about 1100° C. With those conditions, the oxygen reacts with the hydrogen to form a plurality of oxygen radicals in the chamber, and the formed oxygen radicals reacts with the wafer to form a silicon oxide film serving as a tunnel oxide film. Such a tunnel oxide film, comparing to that of the conventional furnace technology, has an improved and satisfactory quality.

As understood by a person skilled in the art, the foregoing preferred embodiments of the present invention are illustrations rather than limitations of the present invention. It is intended to cover various modifications and similar arrangements included within the spirit and scope of the appended claims, the scope of which should be accorded the broadest interpretation so as to encompass all such modifications and similar structure.

What is claimed is:

1. A method for fabricating a tunnel oxide film of a flash memory, comprising:
providing a chamber having a wafer therein;
introducing hydrogen and oxygen into the chamber, whereby the chamber has a pressure and a temperature therein;
decreasing the pressure of the chamber to about 5-15 torrs; and
increasing the temperature of the chamber to about 850° C. to about 1100° C., whereby the hydrogen reacts with the oxygen to form a plurality of oxygen radicals, and whereby the oxygen radicals react with the wafer to form a silicon oxide film having a thickness.

2. The method of claim 1, wherein the chamber comprises a plurality of light bulbs for increasing the temperature of the chamber.

3. The method of claim 2, further comprising adjusting the light bulbs to uniform the thickness of the silicon oxide film.

4. The method of claim 1, wherein the volume of the hydrogen divided by the total volume of the hydrogen and the oxygen is ranged from about 1% to about 33%.

5. The method of claim 1, wherein the chamber has only one wafer therein.

6. A method for fabricating a tunnel oxide film of a flash memory, comprising:
generating a plurality of oxygen radicals to react with a wafer in a chamber having a temperature and a pressure, thereby forming a silicon oxide film having a thickness.

7. The method of claim 6, wherein the chamber has a plurality of light bulbs for increasing the temperature of the chamber.

8. The method of claim 7, further comprising a step of adjusting the light bulbs to uniform the thickness of the silicon oxide film.

9. The method of claim 6, wherein the generating step further comprising:
introducing hydrogen and oxygen into the chamber;
decreasing the pressure of the chamber to about 5-15 torrs; and
increasing the temperature of the chamber to about 850° C.-1100° C.,
thereby reacting the hydrogen with the oxygen to form the oxygen radicals.

10. The method of claim 9, wherein the volume of the hydrogen divided by the total volume of the hydrogen and the oxygen is ranged from about 1% to about 33%.

11. A method for forming a tunnel oxide film, comprising:
providing a chamber for performing a reaction of only one wafer having a thickness, wherein the chamber has a temperature and a pressure therein; and
generating a plurality of oxygen radicals to react with the wafer to form a silicon oxide film having a thickness.

12. The method of claim 11, wherein the chamber has a plurality of light bulbs for increasing the temperature of the chamber.

13. The method of claim 12, further comprising a step of adjusting the light bulbs to uniform the thickness of the silicon oxide film.

14. The method of claim 11, wherein the step of generating the oxygen radicals further comprises:
introducing hydrogen and oxygen into the chamber;
decreasing the pressure of the chamber to about 5-15 torrs; and
increasing the temperature of the chamber to about 850° C.-1100° C.,
thereby reacting the hydrogen with the oxygen to form the oxygen radicals ο

15. The method of claim 14, wherein the volume of the hydrogen divided by the total volume of the hydrogen and the oxygen is ranged from about 1% to about 33% ο

16. A method for fabricating a tunnel oxide film, comprising:
providing a chamber for performing a reaction of only one wafer;
introducing hydrogen and oxygen into the chamber; and
conditioning the hydrogen and oxygen to form a plurality of oxygen radicals, thereby reacting the oxygen radicals with the wafer to form the silicon oxide film having a thickness.

17. The method of claim 16, wherein the chamber has a plurality of light bulbs.

18. The method of claim 17, further comprising a step of adjusting the light bulbs to uniform the thickness of the silicon oxide film.
